(19) United States
(12) Patent Application Publication
(10) Pub. No.: US 2004/0119470 A1
(43) Pub. Date: Jun. 24, 2004

(54) Winding type magnetic sensor device and coin discriminating sensor device

(75) Inventors: Masao Yajima, Nagano (JP); Shogo Momose, Nagano (JP)

Correspondence Address: HOGAN & HARTSON L.L.P., 500 S. GRAND AVENUE, SUITE 1900, LOS ANGELES, CA, 90071-2611, US

(73) Assignee: SANKYO SEIKI MFG. CO., LTD.

(21) Appl. No.: 10/651,838

(22) Filed: Aug. 29, 2003

(30) Foreign Application Priority Data
Sep. 13, 2002 (JP) 2002-267820
Sep. 30, 2002 (JP) 2002-287612

(51) Int. Cl. G01R 33/02; G01N 27/72

(52) U.S. Cl. 324/253; 324/244; 324/207.26; 324/224

(57) ABSTRACT

A winding type magnetic sensor device includes a sensor core facing an object to be detected, an excitation coil wound around the sensor core, and a detection coil wound around the sensor core that defects a variation of magnetic flux corresponding to the object to obtain a detection signal for the object. A constant current drive circuit is provided that supplies a constant current to the excitation coil.

### BACKGROUND OF THE INVENTION

1. Field of the Invention

The present invention relates to a winding type magnetic sensor device which is constituted so as to be capable of discriminating, detecting, or measuring an object to be detected by means of detecting the variation of the magnetic flux due to the object to be detected. The magnetic flux is generated by applying an electric current to an excitation coil which is wound around a core and the variation of the magnetic flux is detected with a detection coil. Also, the present invention relates to a coin discriminating sensor device in which the object to be detected is a coin.

2. Description of Related Art

A detecting device is commonly used for detecting an object to be detected such as a magnetic card, a coin or the like, which is inserted or thrown in an ATM, a vending machine, an automatic ticket vending machine or the like. The detecting device is provided with, for example, a winding type magnetic sensor as shown in FIG. 16. The magnetic sensor includes sensor cores SC1 and SC2, which are arranged to be capable of facing a front face and a rear face of an object C to be detected such as a magnetic card, a coin or the like. An excitation coil 3 and a detection coil 4 are wound around the respective sensor cores SC1 and SC2. A magnetic flux generated when an electric current is supplied to the excitation coil 3 acts on the object C magnetically and thus an eddy current is generated in the object C. The variation of the magnetic flux based on the eddy current is detected with the detection coil 4 to obtain a detection signal of the object C to be detected.

The magnetic sensor described above is connected to a discriminating unit, which is not shown in the drawings, for discriminating the object to be detected on the basis of the detection signal. Reference output values for different types of objects to be detected are stored in the discriminating unit in advance. Each of the reference output values is determined based on the output obtained from the detection coil 4 when the object C is passed through between the two sensor cores SC1 and SC2.

More specifically, a difference between a level value of a sensor standby output signal outputted from the detection coil 4 at a sensor standby state, when an object C to be detected does not exist between the two sensor cores SC1 and SC2, and a maximum level value of a detection output signal outputted from the detection coil 4, when the object C is passed through between the two sensor cores SC1 and SC2, is obtained for each type of the respective objects C beforehand. The respective differences are stored as the reference output values in the discriminating unit. These respective reference output values are compared with the above-mentioned detection output signal to discriminate the object to be detected.

When the object C to be detected is a coin, the magnetic sensor is connected with a coin discriminating unit, which is not shown in the drawings, for discriminating a type of the coin. Reference output values for respective types of coins are stored in the coin discriminating unit in advance. The reference output values are determined based on the outputs obtained from the detection coil 4 when each type of coin C is passed through between the two sensor cores SC1 and SC2. More specifically, a difference between a level value of a standby output signal outputted from the detection coil 4 at a standby state when a coin C does not exist between the two sensor cores SC1 and SC2 and a maximum level value of a detection output signal outputted from the detection coil 4 when the coin C passes through between the two sensor cores SC1 and SC2 obtained for each type of the respective coin C beforehand. The differences are respectively stored as the reference output values in the coin discriminating unit. These respective reference output values are compared with the detected coin discrimination signal to perform the discrimination of the type of coin.

The excitation coil 3 generally and widely used in a conventional winding type magnetic sensor is driven by a constant voltage supplied by a constant voltage circuit, for example, shown in FIG. 17. When the winding type magnetic sensor is a coin discriminating sensor, the excitation coil 3 is also driven by a constant voltage supplied by a constant voltage circuit. As a result, when the ambient temperature at which the winding type magnetic sensor is used varies, the following erroneous operations may be caused.

The problems described below may be applied not only to a case which detects an object to be detected such as a magnetic card or a coin but also to cases which perform material discrimination and conductivity measurements for an object other than a magnetic card or a coin, displacement or shape measurements of the object, and clearance measurements with the object.

As shown in FIG. 18, the permeability u of the sensor core SC provided in the winding type magnetic sensor reveals various characteristics with respect to the variation of temperature T in accordance with the characteristics of a magnetic material used in the sensor core SC. For example, the permeability μ of some magnetic materials shows a continuous increase with respect to the variation of the temperature T (see the curve 1), the permeability μ of another magnetic material shows a continuous decrease (see the curve 2), and further another magnetic material shows an increase and then decreases (see the curve 3). In other words, when the temperature in an operating environment of the winding type magnetic sensor changes the sensors sensitivity varies along with the temperature. Therefore, even when the detection signal of the object to be detected is obtained by the difference between the level value of the standby output signal and the level value of the detection output signal, the differences in the levels also varies with the ambient temperature and thus, inaccurate detection of the object may occur.

Further, considering the impedance of such a winding type magnetic sensor, in addition to the variation of the permeability μ due to the temperature variation as described above, the winding resistance value DCR of the excitation coil 3 is also varied according to the variation of the ambient temperature T as shown in FIG. 19. Therefore, the sensor impedance Z of the winding type magnetic sensor is mixed with the variation of the permeability μ due to the temperature variation and the variation of the winding resistance value DCR due to the temperature variation. In other words, in a low drive frequency region where the principal component of the impedance of a drive coil is the winding resistance value DCR, the linear variation of the winding resistance value DCR is larger than the impedance variation of the drive coil due to the variation of the permeability μ by the temperature variation. Thus, the sensor impedance Z increases as the temperature rises. When the drive frequency becomes higher, the inductance component in the sensor impedance becomes larger, and the variation of the sensor impedance Z due to the temperature variation becomes like the characteristic of a magnetic material used in the sensor core SC as shown in FIG. 18. On the other hand, when the drive frequency is set to be at a middle frequency region between the low frequency and the high frequency, the variation of the winding resistance value DCR and the variation of the permeability μ are added together to result in a complicated characteristic in accordance with the drive frequency.

In addition, the conductivity of the object to be detected such as a coin varies together with the variation of the temperature to cause the variation of the eddy current generated in the object. This causes to vary the detection output.

Accordingly, when the excitation coil 3 is driven with a constant voltage as a conventional example, the drive current I in the excitation coil 3 reduces according to the rising in the temperature in the case that the excitation coil 3 is driven at a low frequency with which the sensor impedance Z increases as the temperature rises. Alternatively, in the case that the magnetic sensor using the sensor core SC having the permeability characteristic such as, for example, the curve 1 in FIG. 18 is driven at a high frequency, the drive current I in the excitation coil 3 also reduces. As a result, the sensor output, i.e., the detection signal of the object to be detected decreases as the temperature T rises as shown in FIG. 20, which may cause a problem for the detecting operation of the object.

As described above, the variation of the detection signal of the object to be detected due to the temperature variation which is obtained from the conventional winding type magnetic sensor or coin discriminating sensor, includes a variation component based on the variation of the permeability μ of the sensor core SC, a variation component based on the winding resistance value DCR of the excitation coil 3, and a variation component based on the conductivity of the object. The total variation amount becomes large and complicated. That is to say, in the conventional structure, every individual winding type magnetic sensor or every individual coin discriminating sensor has a different variation characteristic of the detection signal due to the temperature variation, and thus the discriminating accuracy of the object or a coin is not enhanced.

In order to solve these problems, a countermeasure is proposed, in which an ambient temperature is measured by a temperature detecting element such as a thermistor provided on a circuit section or a sensor portion to correct the detection signal of the object to be detected in accordance with the measured temperature. However, since it is difficult to accurately measure the temperature of the required sensor portion, the correction is not accurate and furthermore the sensor device becomes expensive.

In view of the problems described above, it is advantages of the present invention to provide a winding type magnetic sensor device and a coin discriminating sensor device capable of easily and accurately discriminating the object to be detected with a simple structure.

### SUMMARY OF THE INVENTION

In accordance with an embodiment of the present invention, there is provided a winding type magnetic sensor device including a sensor core facing an object to be detected, an excitation coil wound around the sensor core and, a detection coil wound around the sensor core that defects a variation of the magnetic flux corresponding to the object to obtain a detection signal of the object. A constant current drive circuit is provided that supplies a constant current to the excitation coil. In this case, a common coil may be used for both of the excitation coil and the detection coil, or discrete coils may be used therefor.

According to the winding type magnetic sensor device having such a constitution, since the excitation coil is driven by the constant current, the detection signal for the object to be detected is obtained from the detection coil in such a manner that the variation based on the winding resistance value DCR of the excitation coil due to a temperature variation can be excluded. Also, the temperature in the sensor portion can be estimated by measuring the output of the excitation coil. Accordingly, on the basis of the estimated temperature, the detection signal for the object to be detected can be obtained in such a manner that the variations of the permeability of the sensor core and the conductivity of the object due to the temperature variation are excluded. Therefore, the winding type magnetic sensor device can be easily obtained with little error with respect to the variation of the ambient temperature.

Also, according to the winding type magnetic sensor device having such a constitution, even in a sensor standby state when the object to be detected does not face the sensor core, and in an operating state that the object faces the sensor core, the temperature of the excitation coil, i.e., the temperature of the magnetic sensor can be estimated on the basis of the level value of the drive voltage across the excitation coil driven by the constant current drive circuit.

In accordance with an embodiment of the present invention, a low frequency signal for temperature detection is applied to the excitation coil in order to estimate the temperature of the excitation coil and the temperature of the excitation coil is estimated on the basis of the output value of the low frequency signal. In this case, a direct current signal is preferable for the low frequency signal to exclude an inductance component of the coil. However, a low frequency signal can be sufficiently used because the ratio of the inductance component of the coil is reduced. As described above, when the low frequency signal is applied to the excitation coil, the variation due to the temperature can be handled only as the winding resistance value DCR component of the excitation coil, which varies almost linearly, and thus the temperature of the excitation coil can be estimated with a high degree of accuracy.

When the temperature of the excitation coil can be estimated, this is the temperature of the magnetic sensor itself. Therefore, a correction unit for the variation due to the temperature can be provided on the basis of the estimated temperature of the excitation coil to correct the detection signal for the object to be detected, and the corrected output value with a high degree of reliability can be attained.

The low frequency signal for temperature detection can be used also as a detection signal, which is applied to the excitation coil to detect or discriminate the object to be detected. On the other hand, even when the detection signal which is applied to the excitation coil to detect or discriminate the object to be detected, is a low frequency signal, another lower frequency signal than the low frequency signal for the detection signal can be used as a signal for temperature detection.

When a high frequency signal is preferable used as the detection signal for detecting the object to be detected, an AC signal applied to the excitation coil is preferable to be a signal which is added to a low frequency signal for temperature detection to a high frequency signal for discriminating the object to be detected. As described above, when the signal for the discrimination of the object to be detected and the signal for temperature detection are added to each other, the most suitable frequency for the respective purposes can be selected. For example, when a high frequency signal is used as the signal for the discrimination of the object, the sensor device can be constituted so as to be suitable to detect the displacement or shape of the object.

The detection coil for the atemperature may be arranged within a sensor portion as another coil other than the excitation coil and may be also driven by another constant current drive circuit. This enables measurement of the temperature in an arbitrary place in the sensor device.

According to the winding type magnetic sensor device having such a structure, the temperature in the sensor can be measured accurately. Therefore, by using the temperature characteristic of the permeability μ of the sensor core SC measured in advance, and by using the temperature characteristic of the object to be detected in advance, the winding type magnetic sensor device can acquire a total correction value for a certain temperature. Accordingly, the detection signal of the object can be easily corrected with a high degree of accuracy by applying the estimated temperature to a correction unit.

For example, a low frequency signal for temperature detection applied to the excitation coil is taken out as an output from the voltage across the excitation coil through a low pass filter. The temperature of the excitation coil can be acquired as an estimated value from the above-mentioned output based on the winding resistance value of the excitation coil. Also, since the material of the object to be detected which is detected or discriminated by the magnetic sensor device is known in advance, the total variation based on the variation due to the temperature of the permeability of the sensor core corresponding to the estimated temperature and the variation due to the temperature of the eddy current generated in the object can be acquired in advance on the basis of the estimated temperature. Therefore, the total variation corresponding to the estimated temperature can be stored in the memory to correct the detection output of the object. The magnetic sensor device may be constituted in such a manner that the total variation is automatically excluded from the output of the detection signal to obtain the corrected detection output of the object.

Preferably, the winding type magnetic sensor device is provided with a voltage-temperature table determined by the relationship of the voltage and the temperature based on the winding resistance value of the excitation coil. The voltage-temperature table is constituted so that the voltage detected by measuring the voltage across the excitation coil is related to the temperature of the excitation coil based on the winding resistance value of the excitation coil. The winding type magnetic sensor device is also provided with a correction table determined by a relationship of an output variation and temperature on the basis of a variation of the permeability of the sensor core due to the temperature variation and a variation of the eddy current generated in the object due to the temperature variation. Therefore, the corrected detection output of the object can be easily obtained by using the voltage-temperature table and the correction table.

For temperature detection, it is preferable to use the excitation coil which is wound around the sensor core as the temperature detection coil in order to simplify the constitution of the sensor. However, a temperature detection coil which is separate from the excitation coil may be wound around the sensor core, and a separate constant current drive circuit may be provided to supply a constant current to the temperature detection coil.

In accordance with another embodiment of the present invention, there is provided a coin discriminating sensor device including a sensor core, a coin to be discriminated, an excitation coil wound around the sensor core, a detection coil wound around the sensor core that detects a variation of a magnetic flux corresponding to the coin in order to obtain a detection signal of the coin, and a constant current drive circuit supplying a constant current to the excitation coil.

In this case, a common coil may be used for both of the excitation coil and the detection coil, or discrete coils may be used therefor.

According to the coin discriminating sensor device having such a constitution, since the excitation coil is driven by the constant current, the detection signal of the coin is obtained from the detection coil so that the variation of the winding impedance of the excitation coil due to the temperature variation can be excluded. Therefore, the coin discriminating magnetic sensor device can be easily obtained with little error with respect to the variation of the ambient temperature.

In accordance with an embodiment of the present invention, the coin discriminating magnetic sensor device is provided with a correction unit for correcting the variation of the detection signal outputted from the detection coil, which is based on the variation of the permeability of the sensor core due to the variation of the temperature, on the basis of the level of a standby output signal outputted from the detection coil at a sensor standby state when a coin does not face the sensor core.

Further, the coin discriminating magnetic sensor device may be provided with a correction unit for correcting the detection signal detected from the detection coil to obtain a coin discriminating signal. The correction unit corrects the detection signal on the basis of an estimated temperature, which is estimated by detecting a voltage across the excitation coil driven by the constant current drive circuit.

Preferably, a low frequency signal for temperature detection is applied to the excitation coil in order to estimate the temperature of the excitation coil, and the temperature of the excitation coil is estimated on the basis of the output value of the low frequency signal. In this case, a direct current signal is preferable for the low frequency signal to exclude an inductance component of the coil. However, a low frequency signal can be also sufficiently used because the ratio of the inductance component of the coil is reduced.

When the temperature of the excitation coil can be estimated, this is the temperature of the sensor itself. Therefore, a correction unit for the variation due to the temperature is provided on the basis of the estimated temperature of the excitation coil to correct the coin discriminating signal for the coin and thus the corrected output value can attain high reliability.

According to the coin discriminating sensor device having such a constitution, an ambient temperature of the coin discriminating sensor device can be promptly estimated by using the temperature characteristic of the permeability μ of the sensor core SC measured in advance, and by using the temperature characteristic of the eddy current generated in the coin, which is measured in advance, when the excitation coil is driven by the constant current drive circuit. Accordingly, the discriminating signal of the coin can be easily corrected with a high degree of accuracy by applying the estimated temperature to the correction unit.

When a material whose permeability monotonously increases as the temperature rises is selected as the sensor core in the present invention, the monotonously increasing change of the permeability can be set to compensate for the variation of the detection signal from the detection coil, which is based on the variation of the conductivity of the coin due to the temperature variation. In this case, the variation of the permeability can be set to cancel the variation of conductivity of the coin due to the variation of the temperature. Therefore, the coin discriminating signal in which the variation due to the temperature is corrected can be easily obtained.

Preferably, the constant current drive circuit is disposed in the vicinity of the sensor core. In this case, long wiring is not necessary and thus the stability of the circuit operation such as the prevention of oscillation and the improvement of the SN ratio can be ensured.

Further, when a plurality of sensor cores are driven by a plurality of different frequencies, the constant current drive circuits are preferably constituted so as to be driven with the plurality of different frequencies formed by dividing the output of one oscillator. Therefore, phase matched frequencies can be simply formed, and thus the generation of a beat and fluctuation of the output can be prevented.

Other features and advantages of the invention will be apparent from the following description, taken in conjunction with the accompanying drawings that illustrate, by way of example, various features of embodiments of the invention.

### BRIEF DESCRIPTION OF DRAWINGS

FIG. 1 is an enlarged explanatory side view of a magnetic sensor used in a winding type magnetic sensor device in accordance with an embodiment of the present invention.

FIG. 2 is an explanatory perspective view, which shows a positional relationship between the magnetic sensor of the winding type magnetic sensor device and an object to be detected shown in FIG. 1.

FIG. 3 is a circuit diagram, which shows an example of a constant current drive circuit.

FIG. 4 is a block diagram, which shows a schematic constitution of an entire winding type magnetic sensor device in accordance with an embodiment of the present invention.

FIG. 5 is a block diagram, which shows an example of an excitation/detection circuit used in the winding type magnetic sensor device shown in FIG. 4.

FIG. 6 is a block diagram, which shows an example of a drive voltage detection circuit used in the winding type magnetic sensor device shown in FIG. 4.

FIG. 7 is a flowchart, which shows an example of a correction procedure of the detection signal of the object to be detected.

FIG. 8 is a block diagram, which shows an example of a DCR detection circuit.

FIG. 9 is a graph, which shows measured output results of the drive voltage of the excitation coil with respect to the temperature variation with the DCR detection circuit shown in FIG. 8 when the excitation coil is driven by the constant current drive circuit.

FIG. 10 is a graph, which shows measured standby output results of the drive voltage of the excitation coil with respect to the temperature variation with the DCR detection circuit shown in FIG. 8.

FIG. 11 is a block diagram, which shows a constitutional example in which the DCR detection circuit shown in FIG. 8 is applied to an actual winding type magnetic sensor device.

FIG. 12 is a block diagram which shows an example of a drive circuit when a plurality of winding type magnetic sensors are driven with different frequencies.

FIG. 13 is an explanatory side view, which shows a schematic constitution of a winding type magnetic sensor in accordance with another embodiment of the present invention.

FIG. 14 is an explanatory plan view, which shows the winding type magnetic sensor shown in FIG. 13.

FIG. 15 is an explanatory side view of a magnetic sensor used in a coin discriminating sensor device in accordance with an embodiment of the present invention.

FIG. 16 is an explanatory side view of a conventional magnetic sensor capable of being applied to the present invention.

FIG. 17 is a block diagram, which shows an example of a conventional constant voltage drive circuit.

FIG. 18 is a graph, which shows relations between the permeability of a sensor core and temperature.

FIG. 19 is a graph, which shows a relation between the winding resistance value DCR of an excitation coil and temperature.

FIG. 20 is a graph, which shows a relation between the output of the magnetic sensor and temperature when the excitation coil is driven with the constant voltage drive circuit.

### DETAILED DESCRIPTION OF THE PREFERRED EMBODIMENTS

Preferred embodiments of the present invention will be described in detail below with reference to the accompanying drawings.

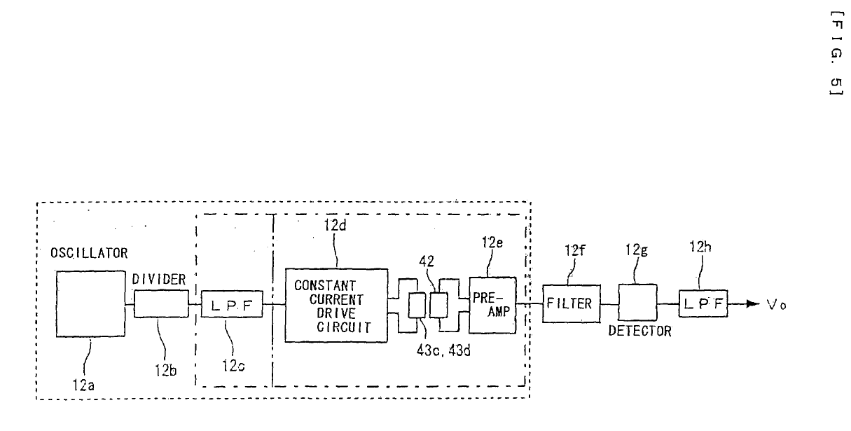

The entire constitution of a detection device for an object to be detected, i.e., a winding type magnetic sensor device according to an embodiment of the present invention is shown in FIG. 4. An excitation/detection circuit 12 for driving an excitation coil and detecting an output of a detection coil is connected with a magnetic sensor 11 described below. The detection signal of the object to be detected, which is obtained from the excitation/detection circuit 12, is sent to a central processing unit (CPU) 14 through an analog to digital (A/D) converter 13, where a final detection signal is obtained. The magnetic sensor 11 is also connected with a drive voltage detection circuit 15, which detects a drive voltage across the excitation coil in order to detect the temperature of the excitation coil. The temperature of the excitation coil is detected by means of sending a signal outputted from the drive voltage detection circuit 15 to the CPU 14 through an A/D converter 16 and temperature correction of the detection signal of the object to be detected is executed by using the temperature.

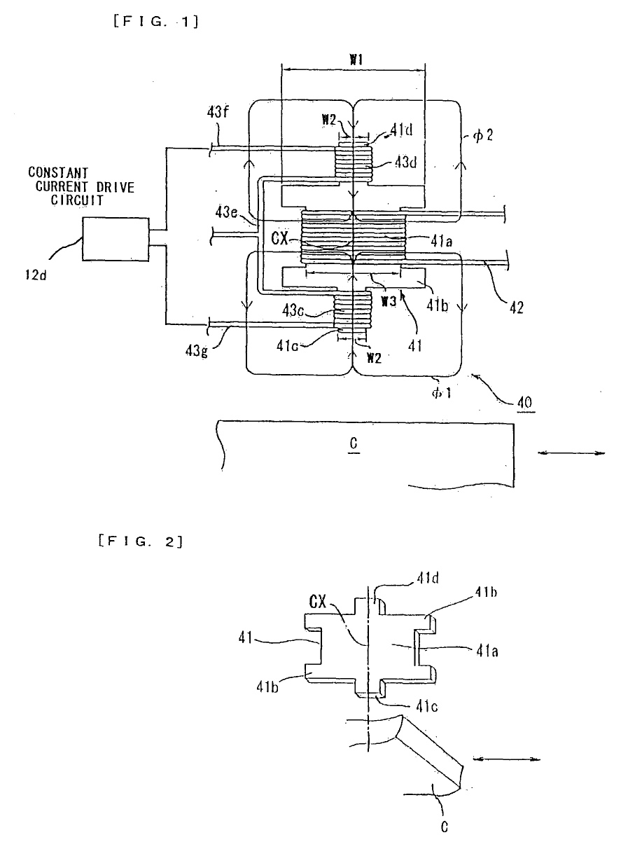

A winding type magnetic sensor 40, which is shown in FIGS. 1 and 2, for example, may be used as the magnetic sensor 11. The winding type magnetic sensor 40 can be used as a displacement sensor for detecting a displacement of the object to be detected, an integrate circuit (IC) contact detection sensor for detecting IC contacts of an IC card, or a coin discriminating sensor for discriminating types of coins, which are, for example, inserted into a vending machine. The winding type magnetic sensor 40 is connected with a circuit control section not shown in the drawing.

The winding type magnetic sensor 40 has a magnetic differential type structure in which a detection coil 42 is wound around a center base core part 41a of a sensor core body 41, which includes one piece of a sheet-shaped magnetic member. A pair of axial end core parts 41c and 41d are integrally formed on upper and lower sides of the center base core part 41a via engaging flange parts 41b, which are respectively formed with the center base core part 41a in an integral manner. Excitation Coils 43c and 43d are respectively wound around the axial end core parts 41c and 41d.

The lower axial end core part 41c is arranged so as to be capable of facing with the object C to be detected. In this embodiment, the direction of an axis CX, which is the direction from the axial end core part 41c to the axial end core part 41d through the center base core part 41a, is set to be substantially perpendicular to a relatively moving direction of the object C to be detected. The object C may be reciprocated with respect to the axial end core part 41c along a direction substantially perpendicular to the axis CX or along a direction of the axis CX. The axial end core part 41c and the object C mutually approach and are apart from each other with an opposed state, and when the axial end core part 41c and the object C are opposed to each other within an appropriate area, the existence of the object C or its moving quantity can be detected. The sensor device may be constituted in such a manner that the object C is fixed and the winding type magnetic sensor 40 moves.

In the winding type magnetic sensor 40 according to the present embodiment having such a structure, the detection output obtained from the detection coil 42 is based on the magnetic field corresponding to the sum of the opposing magnetic fields φ1 and φ2 in the opposite directions, which are generated by a pair of the excitation coils 43c and 43d as shown in FIG. 1. Accordingly, when the object C to be detected does not exist, or the object C is present at a distant place (infinity) sufficient from the winding type magnetic sensor 40, the absolute values of the opposing magnetic fields φ1 and φ2 in the opposite directions are equal to each other (|φ1|=|2|), and the output from the detection coil 42 is “zero”.

On the other hand, when the winding type magnetic sensor 40 and the object C to be detected are relatively approached so that the object C is present within the appropriate area, an eddy current generated in the object C changes corresponding to the variation of the distance between the magnetic sensor 40 and the object C. Accordingly, the opposing magnetic fields φ1 and φ2 in the opposite directions are changed and the magnetic field φ1 becomes smaller. Also, the differential output at this time is obtained from the detection coil 42 on the basis of the magnetic field corresponding to the difference of the absolute value of the opposing magnetic fields φ1 and φ2(|φ1|−|φ2|).

The excitation/detection circuit 12 used in the winding type magnetic sensor device described above is constituted, for example, as shown in FIG. 5.

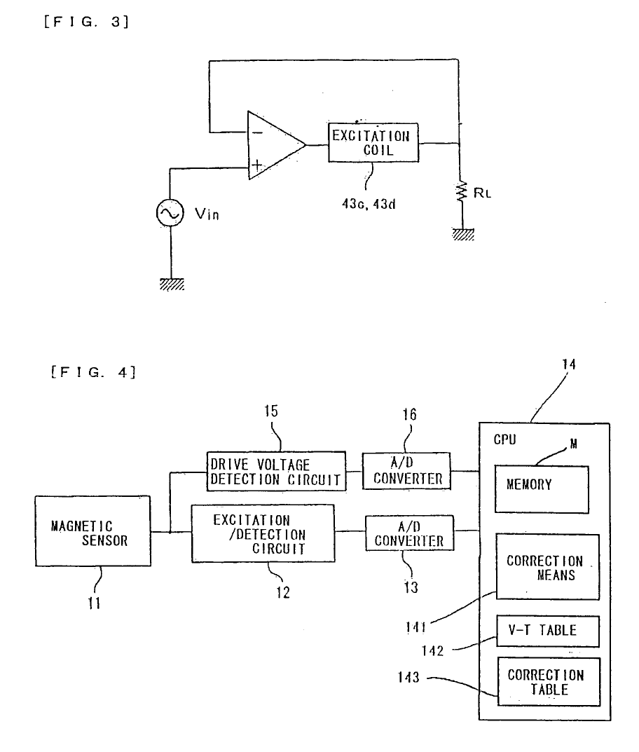

A clock signal provided by appropriately dividing an output from a quartz oscillator 12a with a divider 12b is sent to a constant current drive circuit 12d through a low pass filter (LPF) 12c. The constant current drive circuit 12d is constituted, for example, as shown in FIG. 3, so as to supply a constant drive current to the excitation coils 43c and 43d all the time, as described above.

In FIG. 5, a preamplifier 12e is connected on the output side of the detection coil 42 and the output from the preamplifier 12e is changed into a detection signal V0 of the object to be detected through a band pass filter 12f, a detector 12g and a low pass filter (LPF) 12h.

A constant current drive circuit as shown in FIG. 3 which drives the excitation coils 43c and 43d with a constant current is used as a constant current drive circuit according to an embodiment of the present invention. In the constant current drive circuit shown in FIG. 3, a feedback is formed in such a manner that an input voltage Vin and an end voltage of a pure resistor (constant current setting resistance) RL always become the same. That is, what is called, a virtual short circuit state of the input terminals is formed.

Accordingly, the current flowing through the resistor RL becomes (input voltage Vin)/(the resistance of the current setting resistor RL). Here, when a sine wave with frequency f is supposed to be used as the input voltage Vin, the current flowing in the excitation coils 43c and 43d and the resistor RL can be in a sine wave shape. And, even if the winding resistance value DCR and inductance L in the excitation coils 43c and 43d vary, the relation described above is maintained unless the output of an operational amplifier is not saturated. Accordingly, even if the impedance of the excitation coils 43c and 43d varies, the excitation coils 43c and 43d can be always driven with a constant current value. For example, when a sine wave of 1 Vp-p (volt peak to peak) is applied to the input voltage Vin, a constant current of 100 mAp-p (milli-ampere peak to peak) in a sine wave shape flows in the resistor RL of 10 Ω.

In the constant current drive circuit 12d shown in FIG. 3, since the impedance viewed from the excitation coil side is high, and thus, when a long wiring is used between the excitation coil and the constant current drive circuit, the circuit may easily become unstable to cause an oscillation or deterioration of the signal to noise (S/N) ratio. Therefore, preferably the constant current drive circuit 12d, the preamplifier 12e connected with the detection coil 42, and the like in the portion which is encircled with the broken lines in FIG. 5 are assembled within a sensor housing or arranged in the vicinity of the sensor. When constituted as described above, the operation on the drive circuit side is stabilized and the SN ratio is improved, and thus the stability of the sensor device is secured and improvement of the SN ratio of the sensor device is achieved.

In this embodiment, a sine wave with a low frequency is obtained by using the oscillator 12a and the low pass filter (LPF) 12c shown in FIG. 5 and the low frequency signal is used in the excitation coils 43c and 43d for both of temperature detection and signal detection for detecting the object to be detected. In FIG. 5, a left side portion from the one-dot chain line in the drawing may be arranged outside of the sensor device without forming integral with the sensor device for supplying the signal from the outside, or a left side portion from the two-dot chain line may be arranged outside.

In the case that a plurality of magnetic sensors whose drive frequencies are different from each other are adjacently arranged and when there exist phase shifts between the plurality of magnetic sensors, a beat may be generated to cause an output fluctuation. In this case, only one common oscillator 12a is preferably used to drive the respective magnetic sensors. Therefore, the frequencies whose phases are matched can be readily prepared with dividers.

In the winding type magnetic sensor device according to an embodiment having such a structure, the excitation coils 43c and 43d are driven with the constant current supplied from the constant current drive circuit 12d. Therefore, the variation of the detection signal of the object to be detected due to the temperature variation provided from the winding type magnetic sensor device is in a state that the impedance variation of the winding of the excitation coils 43c and 43d are excluded and correspond to the variation based on the permeability μ of the sensor core SC due to the temperature variation. Accordingly, the winding type magnetic sensor device with little error with respect to the variation of environmental temperature can be easily obtained.

As a result, for example, by means that the temperature characteristic of the permeability μ of the sensor core SC is determined and memorized in a memory provided in the CPU 14 in advance, and the temperature characteristic of the applied voltage from the constant current drive circuit 12d to the excitation coils 43c and 43d in the drive voltage detection circuit 15 is determined and memorized in the memory in advance, the environmental temperature of the winding type magnetic sensor can be promptly estimated. The estimated temperature can be used in a correction unit 141 provided in the CPU 14 to be capable of easy and accurate correcting due to the temperature variation of the detection signal of the object to be detected.

For the correction of the variation due to the temperature variation of the detection signal of the object to be detected by the above-mentioned correction means 141, a particularly satisfactory result is obtained in the case when the permeability μ of the sensor core SC varies monotonously with the temperature. The sensor core, which reveals such a monotonous characteristic in the range of an ordinary temperature, can be readily obtained and preferably used.

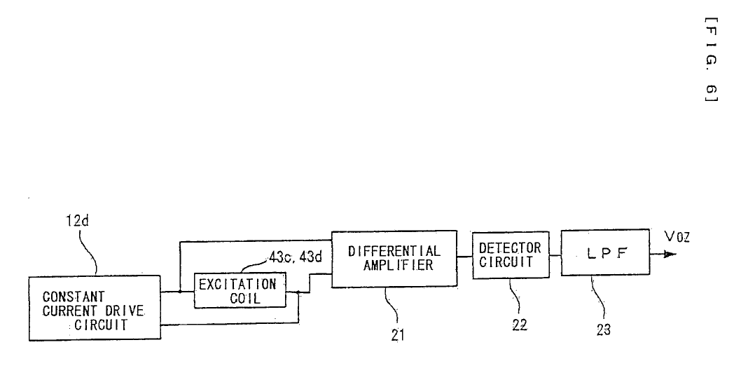

The drive voltage detection circuit 15 described above can be constituted, for example, as an embodiment shown in FIG. 6. The drive voltage detection circuit shown in FIG. 6 is constituted so as to detect a low frequency signal for temperature detection with a differential amplifier 21 as a voltage across the excitation coils 43c and 43d. The output from the differential amplifier 21 is passed through a detector 22 and a low pass filter (LPF) 23 to obtain a drive voltage V0Z of the excitation coils 43c and 43d.

When the drive frequency for the winding type magnetic sensor device having the sensor core is low and the inductance in the drive frequency is small, the impedance of the coil is dominated by the winding resistance value DCR and the contribution ratio of the impedance is determined by the square of the cos θ. Therefore, most of the impedance of the coil is the component of the winding resistance value DCR although it is different based on its core shape, number of turns and frequency. Accordingly, it is preferable to use a low frequency as the drive frequency of the sensor core in order to determine the variation of the winding resistance value DCR readily.

The relation between the drive voltage detected of the excitation coil and the temperature are determined in advance by the data measured beforehand and stored as tables or mathematical expressions in the CPU 14 of the winding type magnetic sensor device (see FIG. 4).

According to an embodiment of the present invention, a V-T table (voltage/temperature) 142 is provided in the CPU 14. The relationship between the voltage based on the winding resistance value of the excitation coil and temperature is written in the V-T table 142. A correction table 143 is also provided in the CPU 14. The correction table 143 has the relationship between the temperature and the output variation based on the variation of the permeability of the sensor core due to the temperature variation and the variation of the eddy current generated in the object to be detected due to the temperature variation. Therefore, the corrected detection output of the object to be detected can be obtained on the basis of the correction table 143.

The effective value of the voltage across the excitation coil is obtained by the drive voltage detection circuit 15 and compared in the correction unit 141 provided in the CPU 14 to estimate the temperature of the excitation coil at the present time. The correction of the detection signal of the object to be detected is performed on the basis of the estimated temperature as follows.

For example, a flow of correction with respect to the temperature variation is executed in the CPU 14 as shown in FIG. 7. In this example, the temperature of the magnetic sensor is determined at a standby state when the object to be detected does not pass through.

When the correcting operation starts, reading of the latest estimated temperature data at the present time is executed (step 1). Then, when a state that the object C to be detected, for example, a coin is not present is confirmed (“No” in step 2), the temperature estimation of the excitation coil is executed on the basis of the relationship of the drive voltage across the excitation coil and the temperature (step 3). The estimated temperature of the excitation coil obtained as described above is written in an appropriate memory M in the CPU 14 and updated regularly. And, when the object C is actually inserted and passed through the winding type magnetic sensor (“Yes” in step 2), the estimated temperature value read from the memory M is used to execute a correction operation of the detection signal of the object (step 4).

The inductance of a coil becomes larger in proportion as the frequency increases. Therefore, when the drive frequency applied to the excitation coil is set to be higher, the ratio of the inductance L of the coil occupied in the impedance of the excitation coil becomes higher. Accordingly, it is not preferable to use a high frequency for temperature detection.

Specifically, as shown in the following Table 1, even in the coil, of which the inductance is small and the winding resistance value DCR is large, the contribution ratio of the winding resistance value DCR with respect to the impedance of the coil becomes extremely low at a high frequency.

TABLE 1
Impedance of Excitation Coil

| | | | | | DCR |
|---|---|---|---|---|---|
| | | | | | Contri- |
| Inductance | Impedance | DCR | Z coil | Phase θ | bution |
| L [μh] | ZL [Ω] | [Ω] | [Ω] | [deg] | Ratio |
| Frequency | 100,000 | | | | |
| [Hz] | | | | | |
| Temperature | −10 | | | | |
| [° C.] | | | | | |
| 50.0 | 31.6 | 6.0 | 32.0 | 79.2 | 0.04 |
| Temperature | 60 | | | | |
| [° C.] | | | | | |
| 55.0 | 34.6 | 8.0 | 35.5 | 77.0 | 0.05 |

In this case, it is preferable to use a thermometer that utilizes the temperature characteristics of the core permeability. However, the temperature characteristics of the core material used for the sensor core are not always proper to be used as a thermometer, and thus it is preferable to constitute as follows.

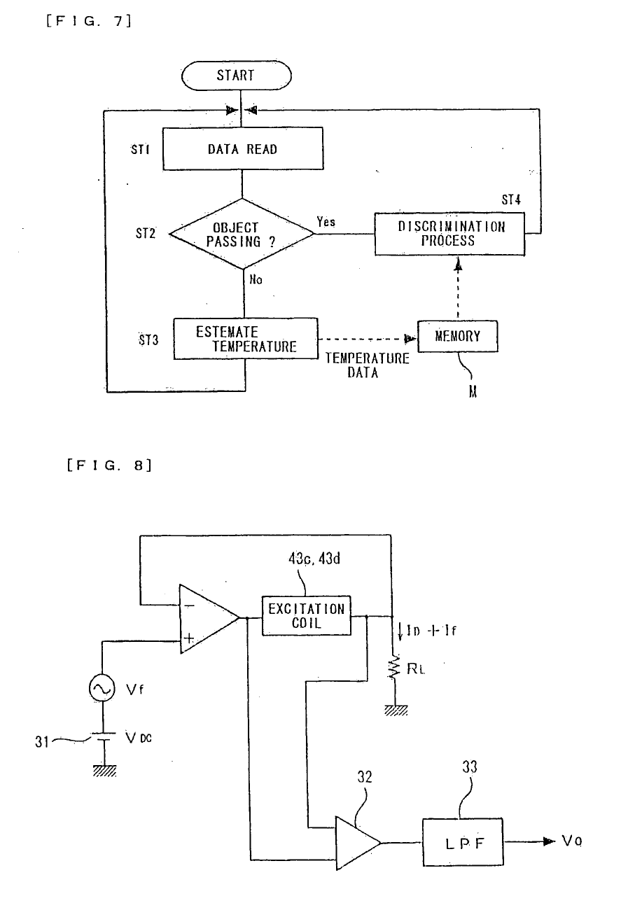

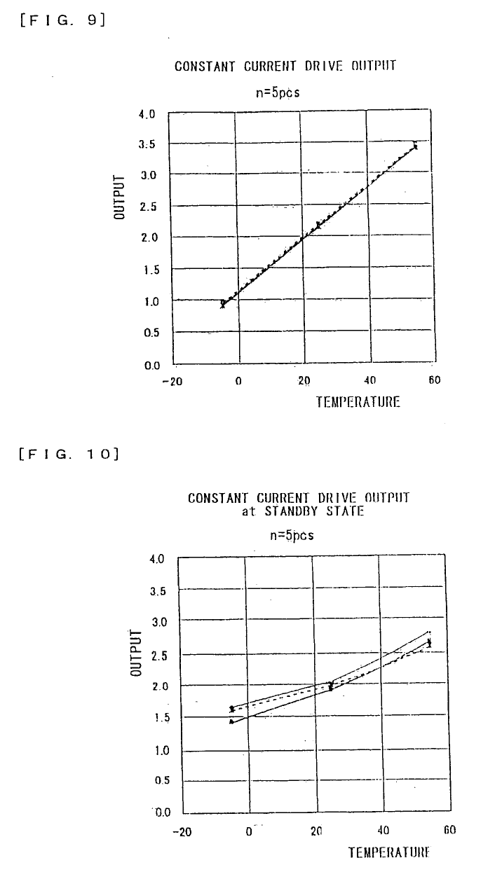

For example, in a DCR detection circuit shown in FIG. 8, a DC bias power supply V_{DC} 31 is provided on the drive side and the DC potential across the excitation coils 43c and 43d is supplied to a preamplifier 32 and a low pass filter (LPF) 33 to obtain a DCR output Vo. The DC bias power supply V_{DC} 31 is considered to be an example of the lowest frequency in a low frequency for temperature detection. As described above, even though a small DC component is added to the excitation coils by the bias power supply V_{DC} 31, the detection signal (=dφ/dt) of the object to be detected which is the sensor output is not affected when the sensor core is not saturated.

The DCR detection circuit shown in FIG. 8 is actually used for five winding type magnetic sensor devices and the constant current drive output due to temperature variation, i.e., the drive voltage V_{0Z} in the excitation coils 43c and 43d is measured for each of the magnetic sensor devices. As a result, a characteristic in which the variation in every winding type magnetic sensor device is small and has a good linearity with respect to the temperature obtained as shown in FIG. 9. Therefore, the same correction data can be applied to all sensors.

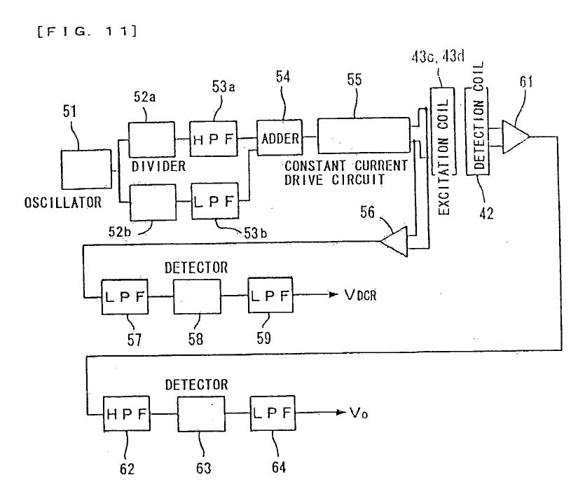

On the other hand, the five winding type magnetic sensors are used in the same manner as described above, and the variation of the detection output due to the temperature variation at a standby state is measured and the results as shown in FIG. 10 are obtained. In this case, the thermometer utilizes a temperature characteristic of the core permeability. According to these measured results, although the variation in every winding type magnetic sensor device becomes relatively large, there is a certain tendency and thus the temperature correction can be performed by determining a correction curve for every winding type magnetic sensor.

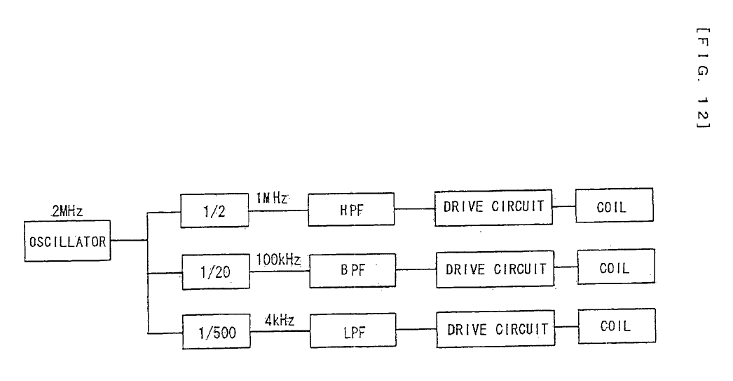

The DCR detection circuit is preferably constituted, for example, as shown in FIG. 11 and used for an actual device.

A clock signal from an oscillator 51 is divided by two dividers 52a and 52b into a high frequency signal, for example, of 1 MHz and a low frequency signal, for example, of 1 kHz which is the frequency in which the DCR is a main component of the impedance of the excitation coil. These high frequency and low frequency signals are sent to and added in an adder 54 through a high pass filter (HPF) 53a and a low pass filter (LPF) 53b. Then, after the high and low frequency signals are added, the added signal is applied to a constant current drive circuit 55, with which a constant drive current is supplied to the excitation coils 43c and 43d.

The voltage applied to the excitation coils 43c and 43d is taken out through an operational amplifier 56 and inputted to a low pass filter (LPF) 57, where the high frequency signal of the above-mentioned 1 MHz is removed. The low frequency signal of 1 KHz is taken out through a detector 58 and a low pass filter (LPF) 59 for eliminating ripples of the detector 58, and the drive voltage across the excitation coils 43c and 43d corresponding to the DCR component is obtained.

A detection output signal from the detection coil 42 is inputted to a preamplifier 61 and then to a high pass filter (HPF) 62, where the low frequency signal of the above-mentioned 1 KHz is removed. The high frequency signal of 1 MHz is inputted to a detector 63 and then to a low pass filter (LPF) 64 for eliminating the ripples in the detector 63 to obtain the detection signal of the object to be detected. According to the embodiment described above, the high frequency signal is used as the detection signal of the object to be detected. Therefore, the magnetic sensor effective to detect the displacement of the object to be detected, the variation of its position and the shape of the object and the like can be obtained. Particularly, detection accuracy and response speed of a magnetic sensor such as a proximity sensor for an object moving at a high speed are improved.

When a plurality of winding type magnetic sensors are driven at different frequencies, a drive circuit, for example, as shown in FIG. 12 is preferably used. In this example, a high frequency signal, for example, of 1 MHz is used for detecting the displacement of the object to be detected, the variation of the position or the shape of the object. An intermediate frequency signal, for example, of 100 KHz is used for the material identification of the object or the measurement of its conductivity, and further, a low frequency signal, for example, of 4 KHz is used for temperature detection. As constituted above, the detection of the object and temperature detection can be performed by using the frequency signal corresponding to the respective purposes. Suppose that when a plurality of frequencies with different phases are used at the same time, the output amplitudes may happen to fluctuate in accordance with the phase difference. However, in the above-mentioned embodiment of the present invention, since the respective drive circuits use the waveforms outputted from only one oscillator, the drive signals with matched phases can be obtained and thus the fluctuation of the output can be eliminated.

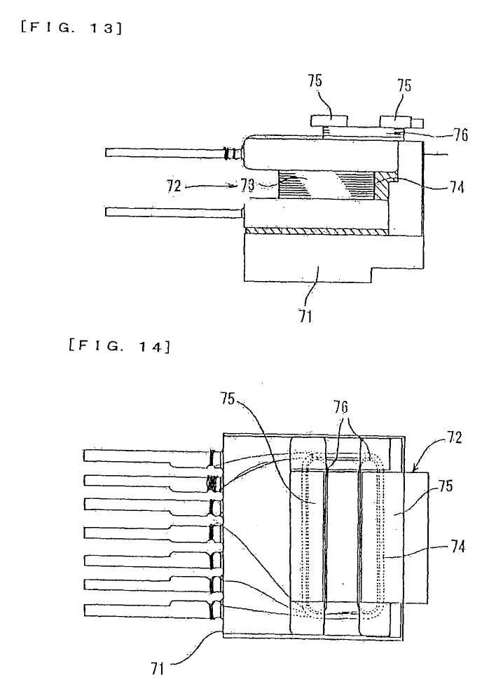

A winding type magnetic sensor shown in FIGS. 13 and 14 is an example of a magnetic sensor, which is preferably provided in a magnetic card reader. The winding type magnetic sensor is constituted so as to detect types such as the types of permeability of a magnetic stripe formed on a magnetic card not shown in the drawings. Concretely, an excitation coil 74 is wound around a base core part 73 of a sensor core 72, which is arranged in a housing 71. In an upper side part in FIG. 13 of the base core part 73, two core facing parts 75 are formed so as to protrude and be capable of facing with a magnetic card as the object to be detected. Detection coils 76 are wound around the respective core facing parts 75 and 75. A sensor device using the winding type magnetic sensor of such a constitution can attain similar operations and effects by performing a constant current drive.

Next, a coin discriminating sensor device in accordance with an embodiment of the present invention will be described below.

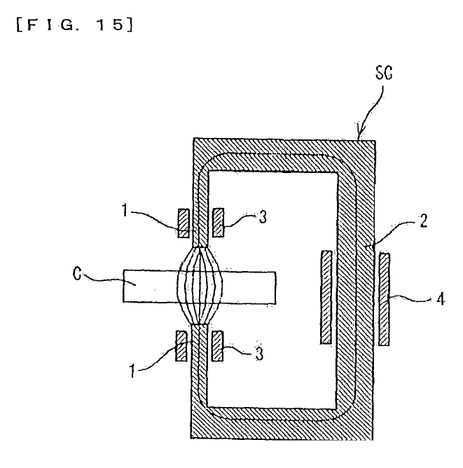

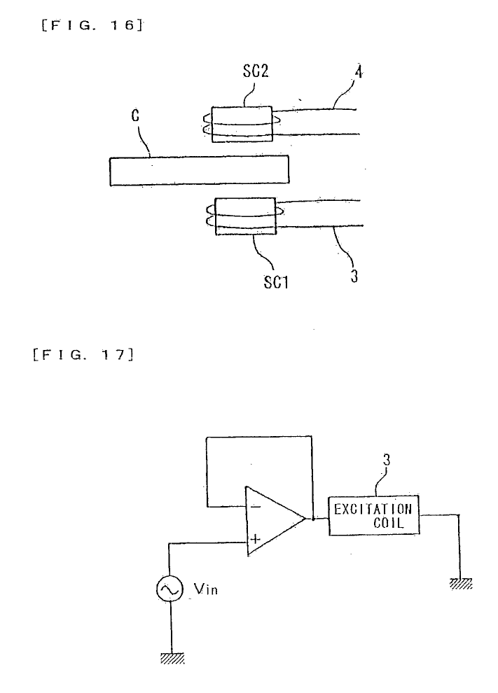

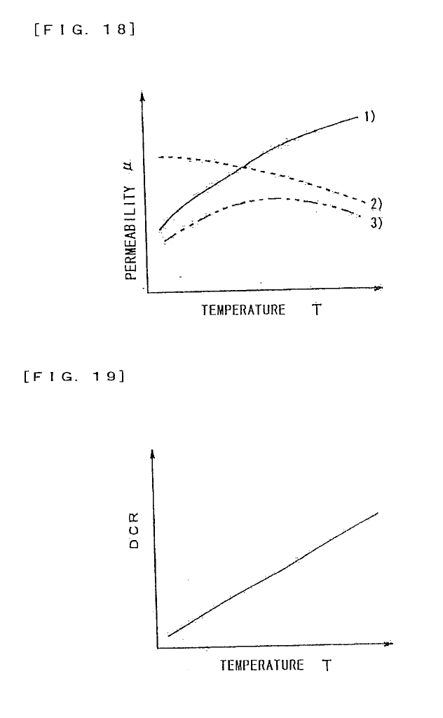

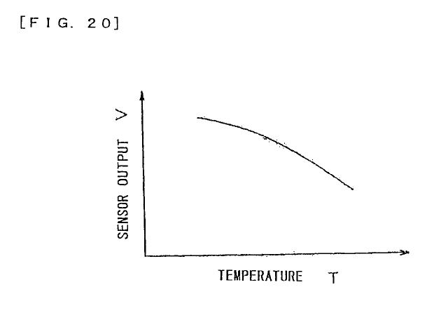

FIG. 15 shows an example of a magnetic sensor in a coin discriminating sensor device so as to detect a type of a coin. Specifically, the magnetic sensor is constituted in such a manner that a coin is passed through between opposing core parts 1 and 1 of a sensor core SC. Excitation coils 3 are respectively wound around the respective opposing core parts 1 and 1 and a detection coil 4 is wound around a base core part 2 of the sensor core SC.

An entire coin discriminating sensor device with the magnetic sensor described above can be basically constituted to be the same as the embodiment shown in FIG. 4. In this case, the coin discriminating sensor device uses the magnetic sensor shown in FIG. 15 for the magnetic sensor 11 in FIG. 4, but another magnetic sensor for coin discrimination may be substituted. In FIG. 4, a coin discriminating signal obtained by means of the excitation/detection circuit 12 is sent through the A/D converter 13 to the CPU 14, where the final detection signal is obtained. Further, the drive voltage detection circuit 15 for detecting the drive voltage of the excitation coil is connected with the magnetic sensor 11. The temperature of the excitation coil is detected from the signal outputted from the drive voltage detection circuit 15 and correction of the coin discriminating signal due to the temperature variation is performed on the basis of the detected temperature.

As for the excitation/detection circuit 12 used in such a coin discriminating sensor device, a constitution, for example, shown in FIG. 5 can be also used. In the constitution shown in FIG. 5, a coin discriminating signal Vo is obtained from the output side of the detection coil 4 through the band pass filter 12f, the detector 12g and the low pass filter (LPF) 12h.

Accordingly, the variation based on the sensor core SC due to the temperature variation of the detection signal outputted from the detection coil 4 can be corrected by detecting the level of a standby output signal outputted from the detection coil 4 at a standby state when a coin is not present between the opposing core parts 1, 1 of the sensor core SC. Therefore, a coin discriminating sensor device can be easily obtained with little error with respect to the variation of the ambient temperature.

Accordingly, for example, the temperature characteristic of the permeability μ of the sensor core SC is measured and memorized in advance, and the temperature characteristic of the applied voltage from the constant current drive circuit 12d to the excitation coils 3 and 3 in the drive voltage detection circuit 15 is measured and memorized in advance, the environmental temperature of the coin discriminating sensor can be promptly estimated. The estimated temperature is used directly or indirectly in a correction means 141 provided in the CPU 14 to be capable of easily and accurately correcting the coin discriminating signal due to the temperature variation.

The drive voltage detection circuit 15 may be constituted like the above-mentioned constitution shown in FIG. 6. In other words, the drive voltage detection circuit 15 shown in FIG. 6 is constituted so as to detect the low frequency signal for the temperature detection with the differential amplifier 21 as a voltage across the excitation coils 3 at a standby state when a coin C is not present between the opposing core parts 1 and 1 of the sensor core SC shown in FIG. 15. The output from the differential amplifier 21 is inputted to the detector 22 and then the low pass filter (LPF) 23 to obtain a drive voltage V_{0Z} of the excitation coils 3.

In the coin discriminating sensor having the sensor core SC shown in FIG. 15, when the drive frequency is low and thus the inductance in the drive frequency is small, the impedance of the coil is dominated by the winding resistance value DCR and the contribution ratio of the impedance is determined by the square of the cos θ. Therefore, most of the impedance of the coil is the component of the winding resistance value DCR although it depends on its core shape, number of turns and frequency. Accordingly, it is preferable to use a low frequency as the drive frequency of the sensor in order to readily determine the variation of the winding resistance value DCR.

The relation between the drive voltage to be detected of the excitation coil and the temperature are determined in advance by the data measured beforehand and stored in the table 142 or by mathematical expressions in the CPU 14 of the coin discriminating sensor device (see FIG. 4). This can be used as the above-mentioned winding type magnetic sensor device. The effective value of the voltage across the excitation coil at a standby state, when a coin C is not present between the opposing core parts 1 of the sensor core SC shown in FIG. 15, is obtained by the drive voltage detection circuit 15 and compared in the correction means 141 provided in the CPU 14 to estimate the temperature of the excitation coil at the present time. The correction of the coin discriminating signal is performed on the basis of the estimated temperature as follows.

For example, the flow of the correction with respect to the temperature variation is executed in the CPU 14 as shown in FIG. 7. In this example, the temperature of the magnetic sensor is determined at a standby state when a coin has not passed through.

When the correcting operation starts, reading of the latest estimated temperature data at the present time is executed (step 1). Then, when a state that a coin C is not present is confirmed (“No” in step 2), the temperature estimation of the excitation coil is executed on the basis of the relationship of the drive voltage across the excitation coil and the temperature (step 3). The estimated temperature of the excitation coil obtained as described above is written in an appropriate memory M in the CPU 14 and updated regularly. And, when a coin C is actually inserted and passed through the coin discriminating sensor (“Yes” in step 2), the estimated temperature value read from the memory M is used to execute a correction operation of the coin discriminating signal of the coin (step 4).

In the above-mentioned example, the temperature estimation of the excitation coil 3 is executed and the correcting operation of the coin discriminating signal is performed by using the estimated temperature value. However, the correcting operation corresponding to this procedure may be automatically executed by using the detected result of the drive voltage of the excitation coil 3 at a standby state without executing the temperature estimation. In this case, although the temperature estimation is not outwardly executed, a substantially same correcting operation is performed.

When a plurality of coin discriminating sensors are used and each coin discriminating sensor is driven with a different frequency, the drive circuit, for example, as shown in FIG. 12 may be used. In this case, a high frequency signal, for example, of 1 MHz is used for detecting the shape of a coin. An intermediate frequency signal, for example, of 100 KHz is used for discriminating the thickness of the coin, and a low frequency signal, for example, of 4 KHz, is used for discriminating the material of the coin. The temperature detection is performed by using the excitation coil which is driven with the low frequency signal. This is because the ratio of the direct-current resistance component in the impedance becomes larger as the frequency becomes lower, and an accurate temperature detection can be attained with the low frequency signal.

According to the constitution described above, the detection of the object to be detected, i.e., a coin and temperature detection can be performed by using the appropriate frequency signals corresponding to the respective purposes. Suppose that when a plurality of frequencies with different phases are used at the same time, the output amplitude may fluctuate in accordance with the situation of the phase difference. However, when such a drive circuit as shown in FIG. 12 is used, the driving signals whose phases are matched can be obtained and the fluctuation of the output is eliminated.

The embodiments of the present invention are described above. However, needless to say, the present invention is not limited to the embodiments described above, and many modifications can be made without departing from the subject matter of the present invention.

For example, the present invention is not limited to the winding type magnetic sensor device and the coin discriminating sensor device described above. The present invention can be similarly applied to various winding type magnetic sensor devices or various coin discriminating sensor devices in which the impedance variation based on the eddy current generated by an object to be detected or a coin by means of the magnetic effect of magnetic flux of an excitation coil is detected with the detection coil.

Further, the detection coil for discriminating an object to be detected or a coin may be not used for temperature detection. In other words, a coil for temperature detection is discretely provided aside from the detection coil and a constant current drive circuit for temperature detection may be provided to supply a constant current to the coil for temperature detection.

As described above, the winding type magnetic sensor device according to the present invention includes the constant current drive circuit which supplies a constant current for driving the excitation coil and thus the excitation coil is driven by the constant current. Therefore, the variation due to the temperature of the detection signal of an object to be detected, which is provided from the winding type magnetic sensor, can be eliminated and thus the winding type magnetic sensor device with little error with respect to the variation of environmental temperature can be easily obtained.

Also, the coin discriminating sensor device according to the present invention includes the constant current drive circuit which supplies a constant current for driving the excitation coil and the excitation coil is driven by the constant current. Therefore, the coil impedance variation of the excitation coil due to the temperature variation in the coin discriminating signal obtained from the coin discriminating sensor can be eliminated and thus the variation due to temperature of the coin discriminating signal can be detected corresponding to the variation based on the temperature variation of the permeability μ of the sensor core SC. Accordingly, the coin discriminating sensor device with little error with respect to the variation of the environmental temperature can be easily obtained. Furthermore, the temperature of the sensor can be accurately measured by driving the excitation coil with a constant current and using a thermometer with the use of the impedance variation according to an environmental temperature.

Also, the coin discriminating sensor device according to the present invention may include the correcting means for correcting the coin discriminating signal on the basis of the present estimated temperature of the excitation coil, which can be estimated from the level value of the drive voltage applied to the excitation coil by the constant current drive circuit at a standby state when a coin is not present. Also, the coin discriminating sensor device according to the present invention may include the correcting means for correcting the coin discriminating signal on the basis of the level value of the output signal outputted from the detection coil at a standby state when a coin is not present between the opposing core parts of the sensor core. Accordingly, these coin discriminating sensor devices can easily correct the coin discriminating signal with a high degree of accuracy by measuring in advance the temperature characteristic of the permeability μ of the sensor core SC or the temperature characteristic of the applied voltage to the excitation coil from the constant current drive circuit and thus the discrimination of a coin can be performed with high precision.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. A winding type magnetic sensor device comprising:
a sensor core facing an object to be detected;
an excitation coil wound around the sensor core;
a detection coil wound around the sensor core that defects a variation of magnetic flux corresponding to the object to obtain a detection signal for the object; and
a constant current drive circuit that supplies a constant current to the excitation coil.

2. The winding type magnetic sensor device according to claim 1, wherein the excitation coil and the detection coil include a common coil.

3. The winding type magnetic sensor device according to claim 1, wherein the excitation coil and the detection coil include discrete coils.

4. The winding type magnetic sensor device according to claim 1, further comprising means for correcting the detection signal of the object based onan estimated temperature of the excitation coil estimated from a drive voltage measured across the excitation coil driven by the constant current drive circuit.

5. The winding type magnetic sensor device according to claim 4, further comprising:
a low frequency signal for temperature detection included in the drive voltage applied to the excitation coil,
wherein the temperature of the excitation coil is estimated based on an output of the low frequency signal.

6. The winding type magnetic sensor device according to claim 5, wherein the low frequency signal is used for obtaining the detection signal of the object.

7. The winding type magnetic sensor device according to claim 5, wherein the low frequency signal for temperature detection is a direct current signal.

8. The winding type magnetic sensor device according to claim 5, further comprising a high frequency signal for discriminating the object to be added to the low frequency signal for temperature detection and applied to the excitation coil.

9. The winding type magnetic sensor device according to claim 5, further comprising a low pass filter for taking out the low frequency signal which is applied across the excitation coil to estimate a temperature of the excitation coil based on a winding resistance value of the excitation coil, the low pass filter being connected to the means for correcting that corrects a variation of permeability of the sensor core due to a temperature variation and a variation of an eddy current generated in the object due to the temperature variation based on the estimated temperature value to obtain an corrected detection output of the object.

10. The winding type magnetic sensor device according to claim 9, further comprising:
a voltage-temperature table determined by a relationship of a voltage and a temperature based on the winding resistance value of the excitation coil, and
a correction table determined by a relationship of an output variation and temperature based on a variation of permeability of the sensor core due to the temperature variation and a variation of an eddy current generated in the object due to the temperature variation,
wherein the corrected detection output of the object is obtained by using at least one of the voltage-temperature table and the correction table.

11. The winding type magnetic sensor device according to claim 1, further comprising:
a detection coil for temperature wound around the sensor core;
a constant current drive circuit for supplying a constant current to the detection coil for temperature, and
means for correcting the detection signal of the object to be detected based on an estimated temperature of the detection coil for temperature, which is estimated from a drive voltage measured across the detection coil for temperature driven by the constant current drive circuit.

12. The winding type magnetic sensor device according to claim 1, wherein the object is a coin.

13. A winding type magnetic sensor device comprising:
a magnetic sensor around which an excitation coil and a detection coil are respectively wound;
an excitation/detection circuit provided for driving the excitation coil and detecting the detection coil and having a constant current drive circuit that supplies a constant current to the excitation coil;
a drive voltage detection circuit connected to the excitation coil of the magnetic sensor that defects a drive voltage of the excitation coil in order to detect a temperature of the excitation coil; and
a discriminating process section to which a detection signal of an object to be detected obtained from the excitation/detection circuit and an output signal from the drive voltage detection circuit are inputted, and from which a corrected detection signal of the object is outputted,
wherein the output signal from the drive voltage detection circuit is used to detect the temperature of the excitation coil and the temperature is used to perform a correction of a variation due to the temperature of the detection signal of the object.

14. A coin discriminating sensor device comprising:
a sensor core capable of facing a coin to be discriminated;
an excitation coil which is wound around the sensor core;
a detection coil wound around the sensor core that defects a variation of a magnetic flux corresponding to the coin, which is generated by applying an electric current to the excitation coil, to obtain a coin discrimination signal; and
a constant current drive circuit for supplying a constant current to the excitation coil.

15. The coin discriminating sensor device according to claim 14, wherein the excitation coil and the detection coil are selecting from the group consisting of common coil and discrete coils.

16. The coin discriminating sensor device according to claim 14, further comprising means for correcting a variation of the detection signal from the detection coil which is based on a variation of permeability of the sensor core due to temperature variation based on a standby output signal outputted from the detection coil at a standby state when a coin is not present.

17. The coin discriminating sensor device according to claim 14, further comprising: means for correcting a detection signal of a coin discrimination signal based on an estimated temperature of the excitation coil which is estimated from a drive voltage measured across the excitation coil driven by the constant current drive circuit.

18. The coin discriminating sensor device according to claim 17, further comprising a relationship determined in the means for correcting in advance between a drive voltage of a low frequency signal for detecting a temperature which is applied to the excitation coil by the constant current drive circuit and a temperature of the excitation coil to determine an estimated temperature.

19. The coin discriminating sensor device according to claim 14, wherein the sensor core is formed of a material whose permeability increases roughly monotonously as the temperature rises, and a variation of the roughly monotonous increase of the permeability is set so as to compensate a variation of the detection signal from the detection coil based on the variation of conductivity due to temperature variation of the coin.

20. The coin discriminating sensor device according to claim 14, wherein the constant current drive circuit is disposed in the vicinity of the sensor core.

21. The coin discriminating sensor device according to claim 20, further comprising:
an oscillator and a plurality of dividers which respectively divide an output of the oscillator to form a plurality of different frequencies,
wherein the constant current drive circuit uses the plurality of different frequencies to drive the sensor core.
